(19) United States
(12) Patent Application Publication
(10) Pub. No.: US 2020/0389125 A1
(43) Pub. Date: Dec. 10, 2020

(54) SOLAR MODULE

(71) Applicant: CLEAN ENERGY FACTORY CO., LTD., Nemuro-shi, Hokkaido (JP)

(72) Inventor: Hiroyuki KAMATA, Tokyo (JP)

(21) Appl. No.: 16/954,709

(22) PCT Filed: Jan. 24, 2019
(86) PCT No.: PCT/JP2019/002158

§ 371 Date: Jun. 17, 2020

(30) Foreign Application Priority Data
Jan. 25, 2018 (JP) 2018-010198

(51) Int. Cl. H02S 50/00; H02S 30/10; H01L 31/05; H01L 31/044

(52) U.S. Cl. CPC H02S 50/00; H01L 31/044; H01L 31/0504; H02S 30/10

(57) ABSTRACT

A tendency to deterioration and a cause of a failure are analyzed based on various information about a power generation status and a location environment of each solar module to enable isolation of each module based on an analysis result, and analysis data on a module operation history is accumulated to enable prediction of a time for replacement of the module. A solar module (1) in which a solar cell array (2) is held in a single plate shape with outer frames (7) and (8) is provided with a plurality of sensors (18) for detecting power generation data for each of the modules and detecting various environment data such as an installation angle, temperature, and illuminance of the solar module (1) at a location of a power generation site where solar strings are laid.

### TECHNICAL FIELD

The present invention relates to a solar module, and more particularly, to a solar module capable of managing operating states of each solar module included in a solar power generation site depending on a variation in operation characteristics of the solar module itself and a variation in installation environment, and capable of operating the entire solar power generation system with high efficiency.

### BACKGROUND ART

A solar power generation (Photo Voltaic: PV) system has a configuration in which units or solar strings, each of which is formed as a single construction unit by connecting, in parallel, solar modules (also referred to as solar panels) obtained by connecting a large number of solar cells in series, are spread and laid on a power generation site. A state where a large number of solar strings are arranged is also referred to as a solar array. As the power generation site, various systems having a variety of power generation capacities are known, ranging from a small system that uses a roof or the like of an independent house or an apartment, to a large system that is also referred to as a so-called mega solar.

A power generation output of each solar string varies greatly depending on environment conditions such as an incident light intensity and an outside air temperature, the temperature of the solar module itself, and the like. If a predetermined output cannot be obtained due to a deficiency (deterioration in power generation capability, damage, or the like) in a single solar module included in a solar string, the module is disconnected from the string and the power generation is continued using the remaining solar modules, thereby making it possible to continue the power generation without a considerable reduction in the amount of power generation. Accordingly, there is a need to take appropriate countermeasures such as monitoring the state of each module, analyzing the content of an abnormality if the abnormality is detected, and isolating the module in which the abnormality has occurred. Note that, for convenience of explanation, the above-described terms can be simplified using words such as a string, a module, and a cell.

Patent Literature 1, Patent Literature 2, Patent Literature 3, and the like disclose the related art relating to a diagnosis technique for a solar power generation system, and the like. Patent Literature 1 discloses a failure diagnosis method for measuring a time period of an observation signal to be sent in response to a measurement signal input between terminals of a solar array and solar strings and an earth, and measuring an observation signal waveform, thereby easily specifying a failure position and a failure type.

According to Patent Literature 2, an input signal is applied to an installed solar array to obtain an actual measurement signal by an actual measurement portion, and a simulation is performed by applying the same input signal to a virtual model fashioned after the array in an installation environment assuming a section in the solar array as a failure section, thereby obtaining a dummy output signal. Further, a method is disclosed in which the actual measurement signal and the dummy output signal are compared, a precision is calculated based on the comparison result, and if the precision is more than or equal to a predetermined value, it is estimated that the assumed failure section is identified as the failure section in the solar array.

According to Patent Literature 3, an inspection unit including a switching portion, an inspection execution portion and a control portion is provided, a cable contact between a plurality of strings and a power conditioner is configured to be switchable from a normally closed state to an open state, and the inspection execution portion can apply an input signal to each string, and can actually measure an output signal as a response from the string. If an inspection start condition is satisfied, a control portion causes the inspection execution portion to execute an inspection after causing the switching portion to perform a switching operation, compares an input signal and an output signal as inspection data to discriminate whether there is a failure or another deficiency in each string, and obtains the inspection result. Further, an inspection apparatus for a solar array that determines a failure if a new deficiency is detected after a lapse of a predetermined time period, and determines a theft if a plurality of new breakages is detected after a lapse of a predetermined time period is disclosed.

### CITATION LIST

### Patent Literature

Patent Literature 1: Japanese Patent Laid-Open No. 2009-21341
Patent Literature 2: Japanese Patent Laid-Open No. 2011-35000
Patent Literature 3: Japanese Patent Laid-Open No. 2013-251581

### SUMMARY OF INVENTION

### Technical Problem

Monitoring and diagnosis of a module abnormality in a solar power generation system of related art are basically performed by monitoring a current and voltage measured at an output end. Therefore, an abnormality state (deterioration in power generation ability, breakdown, or failure) of a solar string formed by connecting, for example, about 10 solar modules in series can be detected, but it is not easy to specify the type of an abnormality or failure in each module included in the string.

It is necessary to constantly monitor an operating state of each solar module and perform the power generation capability and failure diagnoses so as to reduce an operation interruption period of the power generation system that is required to deal with a deterioration in output and interruption due to a degradation in output caused by a failure in a module included in the power generation system, or deterioration in power generation capability, or an external cause (a variation in layout environment), to thereby increase the power generation ability and operation efficiency of the entire power generation system.

An object of the present invention is to provide a solar module that analyzes a tendency to deterioration and a cause of a failure based on various information about a power generation status and a location environment of each solar module to enable isolation of each module based on the analysis result, detects an unexpected event, such as an impact or damage caused on purpose or due to a natural disaster, and accumulates analysis data on operation histories of solar modules to thereby enable prediction of a time for replacement of the module.

### Solution to Problem

To attain the above-described object, according to the present invention, each solar module is provided with a plurality of sensors for detecting power generation data for each of the modules and detecting data, such as an installation angle and temperature of each solar module at a location of a site where strings are laid, and various environment data on the site. Representative configurations of the present invention are described below.

(1) A solar module included in a solar string in a solar power generation site, the solar power generation site including a solar array formed by arranging a large number of the solar strings, and a power conditioner for converting DC power from the solar array into AC power and supplying the AC power to a utilization device. The solar module is formed by arranging a plurality of solar cells. The solar module includes an outer frame that supports the arrangement of the solar cells in a single plate shape. The solar module includes one or more additional function accommodating members installed on the outer frame on an opposite side of a solar light irradiation surface of the solar module. The one or more additional function accommodating members include a terminal connecting portion for connecting output terminals of solar modules in the solar string to connect to an output terminal of another solar string included in the solar strings, and a sensor accommodating portion composed of a power generation information sensor for detecting power generation information for each of the solar strings and an environmental information sensor for detecting environmental information.

(2) The terminal connecting portion according to (1) includes a backflow prevention diode for preventing inflow of a current from another solar module, and a bypass diode for disconnecting the solar module from an output line of the solar string in response to deterioration in a function of the solar module.

(3) The power generation information sensor accommodated in the sensor accommodating portion according to (1) or (2) is composed of an ammeter and a voltmeter.

(4) The environmental information sensor accommodated in the sensor accommodating portion according to any one of (1) to (3) is composed of an environment parameter detection sensor group including an atmospheric pressure sensor, a temperature sensor, a humidity sensor, an illuminance (received light amount) sensor, an elevation angle sensor, a horizontal angle sensor, and an acceleration sensor, the environment parameter detection sensor group further including a GPS, as needed.

(5) The one or more additional function accommodating members according to any one of (1) to (4) include an optimizer accommodating portion.

(6) Each of the one or more additional function accommodating members according to any one of (1) to (4) is a single box body that stores the terminal connecting portion and the sensor accommodating portion.

(7) The optimizer accommodating portion according to (5) is stored in the one or more additional function accommodating members together with the terminal connecting portion and the sensor accommodating portion.

(8) The optimizer accommodating portion according to (5) is stored in an additional function accommodating member different from the additional function accommodating member storing the terminal connecting portion and the sensor accommodating portion.

(9) The terminal connecting portion and the sensor accommodating portion according to (6) are stored in different additional function accommodating members, respectively.

(10) The one or more additional function accommodating members according to (1) are fixed to the outer frame of the solar module.

Note that the present invention is not limited to the above-described configurations and configurations described in embodiments to be described below. Needless to say, the present invention can be modified in various ways without departing from the scope of the technical idea of the present invention. A major feature of the present invention is that various sensors are installed in each solar module.

### Advantageous Effects of Invention

According to the present invention, not only a sensor for detecting a variation in power generation ability of a solar module, but also various sensors for detecting a variation in external condition (environmental variation) specific to a location (installation place) of a solar power generation site are provided to monitor an operating state of the solar module stepwise, perform diagnosis, and disconnect the solar module from solar strings, as needed, if it is diagnosed that a failure has occurred in the solar module. Additionally, required countermeasures can be taken by specifying, for each module, a breakage or deficiency in the module caused on purpose or due to a natural disaster.

With this configuration, it is possible to continuously use normal solar modules for power generation by disconnecting only the solar module in which the power generation ability is lower than a set value from the solar strings, thereby achieving an operation with a high operation efficiency of each solar string and with a high efficiency of the entire solar array.

### BRIEF DESCRIPTION OF DRAWINGS

FIG. 1 are explanatory diagrams each illustrating a solar module according to the present invention, FIG. 1(a) is a plan view illustrating a light-receiving surface, and FIG. 1(b) is a sectional view taken along a line A-A in FIG. 1(a) and is also a principal part sectional view.

FIG. 2 is a partial view illustrating a mounting structure example of an additional function accommodating member provided on a back surface of the solar module according to the present invention.

FIG. 3 is a schematic diagram illustrating an arrangement example of an additional function accommodated in the additional function accommodating member illustrated in FIG. 2.

FIG. 4 is a schematic explanatory diagram illustrating a solar power generation system using the solar modules according to the present invention.

### DESCRIPTION OF EMBODIMENTS

Preferred embodiments of a solar module according to the present invention will be described below in detail with reference to the drawings illustrating the embodiments.

### First Embodiment

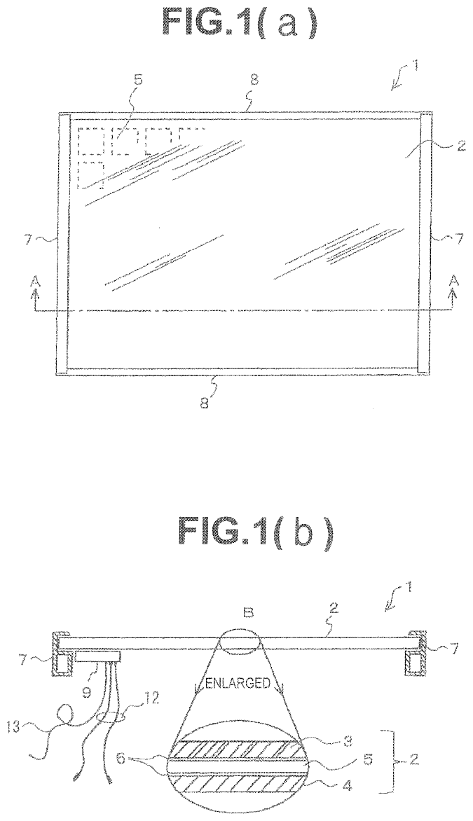

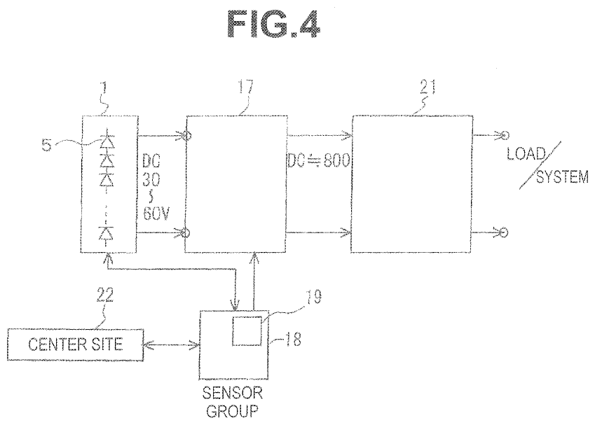

FIG. 1 are explanatory diagrams each illustrating a solar module according to a first embodiment of the present invention. FIG. 1(a) is a plan view illustrating a light-receiving surface (solar light irradiation surface). FIG. 1(b) is a sectional view taken along a line A-A in FIG. 1(a) and is also a principal part sectional view. As described below with reference to FIG. 4, a solar power generation site includes a solar array formed by arranging a large number of solar strings, and a power conditioner for converting DC power from the solar array into AC power and supplying the AC power to a utilization device or a system.

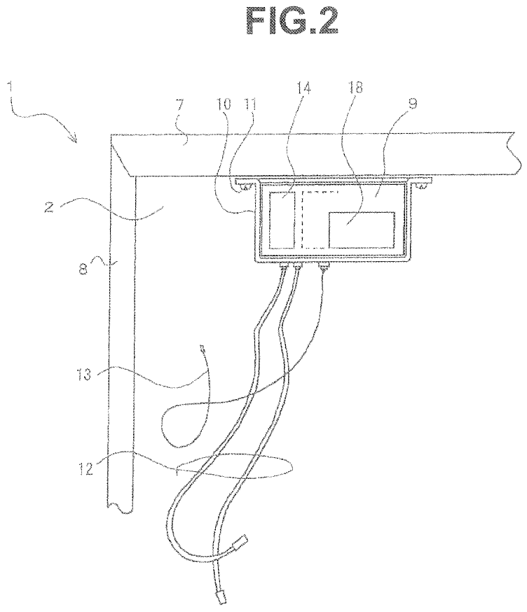

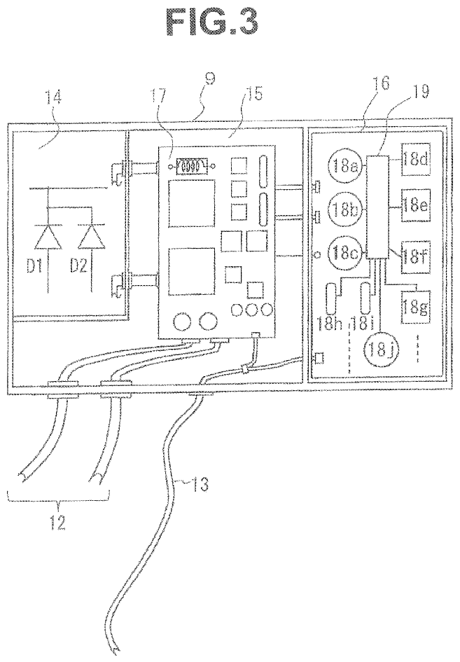

FIG. 2 is a partial view illustrating a mounting structure example of an additional function accommodating member provided on a back surface of the solar module according to the present invention. FIG. 3 is a schematic view illustrating an arrangement example of additional functions accommodated in the additional function accommodating member illustrated in FIG. 2. FIG. 4 is a schematic explanatory diagram illustrating a solar power generation system using the solar module according to the present invention.

Each of the solar strings in the solar power generation site is composed of a plurality of solar modules 1. Each solar module is composed of a cell array 2 formed by arranging a plurality of solar cells 5. Each solar module 1 includes an outer frame that supports the arrangement of the solar cells 5 in a single plate shape. The solar module 1 illustrated in FIG. 1(a) has a rectangular plan view and is composed of a pair of first frames 7 and a pair of second frames 8. In FIG. 1, the first frames 7 correspond to short sides and the second frames 8 correspond to long sides.

The cell array 2 is composed of the solar cells 5 sealed with a sealing material 6 between a front panel 3 and a back panel 4 for which transparent reinforced glass is suitably used as illustrated in an enlargement view of FIG. 1(b).

As illustrated in FIG. 1(b), an additional function accommodating member 9 that is mounted on the outer frame is provided on the side (back surface) opposite to the solar light irradiation surface of the solar module 1. While, in this configuration example, a single additional function accommodating member 9 is provided, one or more other additional function accommodating members which accommodate different contents and are independent from each other can be arranged. However, it is assumed herein that a single additional function accommodating member is used. Output lines 12 for taking out a power generation output and a monitor/control line 13 are drawn out from the additional function accommodating member 9.

The additional function accommodating member 9 illustrated in FIG. 2 is fixed to the inside of the first frames 7 using a bracket 10 with screws 11. In the figure, reference numeral 12 denotes power output lines and reference numeral 13 denotes a monitor/control line.

In FIG. 3, the additional function accommodating member 9 includes a terminal connecting portion 14 for connecting output terminals of the solar modules 1 in the solar strings to connect to an output terminal of another solar string included in the solar strings, and a sensor accommodating portion 16 composed of a power generation information sensor for detecting power generation information for each solar string and a plurality of environmental information sensors 18a to 18j . . . , for detecting various environmental information.

Further, the terminal connecting portion 14 includes a backflow prevention diode D1 for preventing inflow of a current from another solar module, and a bypass diode D2 for disconnecting the solar module from the output lines of the solar strings in response to deterioration in a function of the solar module.

Incidentally, examples of sensors installed in the sensor accommodating portion 16 include an atmospheric pressure sensor 18a, a temperature sensor 18b, a humidity sensor 18c, an illuminance sensor (received light amount sensor) 18d, an elevation angle sensor 18e, a horizontal angle sensor 18f, an acceleration sensor (vibration sensor) 18g, a current sensor 18h, and a voltage sensor 18i. Further, a GPS 18j is desirably installed. A transmission circuit, an antenna, and a battery can be mounted on the GPS 18j or the sensor accommodating portion 16, and positional information about each solar module can be wirelessly transmitted together with an ID of the module itself.

Note that the power generation information sensor accommodated in the sensor accommodating portion 16 is composed of a current sensor (ammeter) 18h and a voltage sensor (voltmeter) 18i. Examples of the sensors also include a sensor for detecting the temperature of each solar module, or a sensor such as an accelerometer for detecting a vibration.

The sensor accommodating portion 16 includes a sensor data calculation unit 19, encodes detected data from the sensors 18a to 18i, and data from the GPS 18j, as needed, and sends the encoded data to the monitor/control line 13. The data on the monitor/control line 13 is transferred to a center site 22 illustrated in FIG. 4, is used for monitoring and control of each solar module, and is stored as an operation history. Based on this data, a degree of deterioration and a time for replacement of each solar module can be determined. Note that these data are desirably transferred by PLC using the so-called output lines 12.

In this configuration example, the additional function accommodating member 9 includes an optimizer accommodating portion 15. An optimizer 17 is a means for optimizing an output of solar power generation with a large variation to thereby obtain stable power for power generation. Data acquired by a sensor group 18 can be used as reference data for the optimizer 17.

An optimizer is generally installed in an output of a solar array. However, in this configuration example, the optimizer is provided at an output end of each solar module 1, and an optimum power generation output is obtained for each solar module. Further, the optimizer may be installed in each string. Accordingly, instead of being accommodated in the additional function accommodating member 9, the optimizer 17 may be installed in an output of the solar array, like in the related art, or may be installed in each solar string.

The additional function accommodating member 9 is a single box body that stores the terminal connecting portion 14 and the sensor accommodating portion 16. Alternatively, the terminal connecting portion 14 and the sensor accommodating portion 16 may be accommodated in different box bodies, respectively, and may be mounted on the outer frame. Further, the optimizer accommodating portion 15 may be a single box body. However, in this configuration example, each of the terminal connecting portion 14, the sensor accommodating portion 16, and the optimizer accommodating portion 15 is a single box body.

As illustrated in FIG. 4, an output voltage of the solar module 1 is about DC 30 V to 60 V, and the output voltage is boosted to about DC 800 V by the optimizer 17. The DC output of the optimizer 17 is converted into AC 100 V or AC 200 V by a power conditioner 21, and the converted output is used for a load of a home electrical appliance or the like, or is sent to a system.

Data acquired by the sensor group 18 installed in the solar module 1 according to the present invention is referred to by the optimizer, or is transferred to the center site 22 that is attached to the power generation site or is remotely located, and is used for monitoring and operation processes.

According to the above-described embodiments of the present invention, not only a sensor for detecting a variation in power generation ability of each solar module, but also various sensors for detecting a variation in environment condition specific to the location of the solar power generation site are provided, thereby making it possible to monitor an operating state of each solar module stepwise, perform diagnosis, predict a time for replacement, and disconnect the solar module from solar strings if it is diagnosed that a failure has occurred in the solar module. Moreover, it is possible to take required countermeasures by specifying, for each module, a breakage or deficiency in a module caused on purpose or due to a natural disaster.

Thus, it is possible to continuously use normal solar modules for power generation by disconnecting only the solar module in which the power generation ability is lower than a set value, or only the solar module which cannot be used due to a damage or the like, from solar strings, thereby improving the operation efficiency of the solar strings and achieving an operation with a high efficiency of the entire solar power generation site. As an additional advantageous effect to be obtained when a GPS is mounted, it is also possible to perform tracking if a theft of a solar module has occurred.

### DESCRIPTION OF SYMBOLS

1 solar module
2 cell array
3 front panel
4 back panel
5 solar cell
6 sealing material
7 first frame
8 second frame
9 additional function accommodating member
10 bracket
11 screw
12 output line
13 monitor/control line
14 terminal connecting portion
15 optimizer accommodating portion
16 sensor accommodating portion
17 optimizer
18 sensor group (18a, . . . )
19 sensor data calculation unit
21 power conditioner
22 center site

1. A solar module included in a solar string in a solar power generation site, the solar power generation site including a solar array formed by arranging a large number of the solar strings, and a power conditioner for converting DC power from the solar array into AC power and supplying the AC power to a utilization device,
wherein the solar module is formed by arranging a plurality of solar cells,
wherein the solar module comprises an outer frame that supports the arrangement of the solar cells in a single plate shape,
wherein the solar module comprises one or more additional function accommodating members installed on the outer frame on an opposite side of a solar light irradiation surface of the solar module, and
wherein the one or more additional function accommodating members include a terminal connecting portion for connecting output terminals of solar modules in the solar string to connect to an output terminal of another solar string included in the solar strings, and a sensor accommodating portion composed of a power generation information sensor for detecting power generation information for each of the solar strings and an environmental information sensor for detecting environmental information.

2. The solar module according to claim 1, wherein the terminal connecting portion includes a backflow prevention diode for preventing inflow of a current from another solar module, and a bypass diode for disconnecting the solar module from an output line of the solar string in response to deterioration in a function of the solar module.

3. The solar module according to claim 1, wherein the power generation information sensor accommodated in the sensor accommodating portion is composed of a current sensor and a voltage sensor.

4. The solar module according to claim 1, wherein the environmental information sensor accommodated in the sensor accommodating portion is composed of an environment parameter detection sensor group including an atmospheric pressure sensor, a temperature sensor, a humidity sensor, an illuminance (received light amount) sensor, an elevation angle sensor, a horizontal angle sensor, and an acceleration sensor, the environment parameter detection sensor group further including a GPS.

5. The solar module according to claim 1, wherein the one or more additional function accommodating members include an optimizer accommodating portion.

6. The solar module according to claim 1, wherein each of the one or more additional function accommodating members is a single box body that stores the terminal connecting portion and the sensor accommodating portion.

7. The solar module according to claim 5, wherein the optimizer accommodating portion is stored in the one or more additional function accommodating members together with the terminal connecting portion and the sensor accommodating portion.

8. The solar module according to claim 5, wherein the optimizer accommodating portion is stored in an additional function accommodating member different from the additional function accommodating member storing the terminal connecting portion and the sensor accommodating portion.

9. The solar module according to claim 6, wherein the terminal connecting portion and the sensor accommodating portion are stored in different additional function accommodating members, respectively.

10. The solar module according to claim 1, wherein the one or more additional function accommodating members are fixed to the outer frame of the solar module.
